(19) United States
(12) Patent Application Publication
(10) Pub. No.: US 2026/0251869 A1
(43) Pub. Date: Aug. 27, 2026

(54) AJINOMOTO BUILD-UP FILM (ABF) BRIDGE FRAME

(71) Applicant: Microchip Technology Incorporated, Chandler, AZ (US)

(72) Inventors: Steve Nagel, Chandler, AZ (US); Bomy Chen, Newark, CA (US)

(21) Appl. No.: 19/455,382

(22) Filed: Jan. 21, 2026

Related U.S. Application Data
(60) Provisional application No. 63/761,571, filed on Feb. 21, 2025.

(51) Int. Cl. G02B 6/42

(52) U.S. Cl. CPC G02B 6/4268; G02B 6/4245; G02B 6/4278

(57) ABSTRACT

Disclosed herein are apparatus, system, method, and computer-readable medium aspects for a panel-level packaging for integrating photonic and electronic components. A system aspect may include a substrate formed from an Ajinomoto Build-Up Film (ABF) material, a photonic integrated circuit (PIC) and an electrical integrated circuit (EIC) mounted on a panel coupled to the substrate, a window formed in the substrate to allow for the placement of a heat spreader, and the heat spreader positioned within the window to dissipate thermal energy generated by at least one of the PIC and the EIC. The panel-level package may function as a pluggable circuit board for use in an electro-optical system. The heat spreader may be thermally coupled to at least one of the PIC and the EIC to enhance heat dissipation efficiency. The substrate may include a plurality of windows containing respective heat spreaders from a plurality of heat spreaders.

### CROSS-REFERENCE TO RELATED APPLICATION

The present application claims priority from U.S. Provisional Patent Application No. 63/761,571, filed Feb. 21, 2025, which is incorporated herein by reference in its entirety.

### TECHNICAL FIELD

The present disclosure relates generally to panel-level packaging for integrated circuits, and more specifically to systems and methods for integrating photonic and electronic components with enhanced thermal management through the use of heat spreaders and immersion cooling compatibility.

### SUMMARY

According to an aspect of one or more examples, there is provided a panel-level packaging system for integrating photonic and electronic components. The system may include a substrate formed from an Ajinomoto Build-Up Film (ABF) material, a photonic integrated circuit (PIC) and an electrical integrated circuit (EIC) mounted on a panel coupled to the substrate, a window formed in the substrate to allow for the placement of a heat spreader, and the heat spreader positioned within the window to dissipate thermal energy generated by at least one of the PIC and the EIC. The panel-level package may function as a pluggable circuit board for use in an electro-optical system. The heat spreader may be thermally coupled to at least one of the PIC and the EIC to enhance heat dissipation efficiency. The substrate may include a plurality of windows containing respective heat spreaders from a plurality of heat spreaders. A size and a shape of each of the plurality of heat spreaders may be configured based on a thermal profile of corresponding ones of the PIC and the EIC. The panel-level package may interface with an immersion cooling system. The substrate may facilitate high-density interconnects between the substrate and the panel.

According to an aspect of one or more examples, there is provided a method for manufacturing a panel-level packaging system for integrating photonic and electronic components. The method may include mounting a photonic integrated circuit (PIC) and an electrical integrated circuit (EIC) on a panel, providing a substrate composed of an Ajinomoto Build-Up Film (ABF) proximate to the panel, forming a window in the substrate to accommodate a heat spreader, and positioning the heat spreader within the window to dissipate thermal energy generated by the PIC and the EIC. The method may include depositing and etching the ABF substrate to form the window. The heat spreader may be positioned using a pick-and-place process. The method may include testing the panel for thermal performance after positioning the heat spreader. The method may include configuring the panel to function as a pluggable component for an electro-optical system. The panel may interface with a dielectric fluid immersion cooling system.

According to an aspect of one or more examples, there is provided a thermal management system for a panel-level package integrating photonic and electronic circuits. The system may include a panel comprising at least one circuit of the photonic and electronic circuits, a substrate coupled to the panel and comprising a plurality of windows corresponding to thermal hotspots in the panel, a plurality of heat spreads positioned within a plurality of windows to dissipate the thermal hotspots, and a dielectric cooling fluid. The panel, the substrate, and the plurality of heat spreaders are submerged in the dielectric cooling fluid. The dielectric cooling fluid may be in a liquid phase. The dielectric cooling fluid may be in a liquid phase and undergo a phase change to a vapor phase upon dissipating the thermal hotspots. The heat spreaders may be removable and replaceable. The heat spreaders may be comprised of a thermally conductive metal or composite material. The thermal management system may include heat spreaders proximate to both top and bottom surfaces of the panel. The panel may include a plurality of circuits of the photonic and electronic circuits arranged in a grid pattern. The windows may be etched to reduce disruption to the conductive traces within the thermal management system. The system may include optical and electrical connectors for interfacing the panel with external systems.

### BRIEF DESCRIPTION OF DRAWINGS

FIG. 1A shows a cross-sectional view of a panel-level packaging system for integrating photonic and electronic components according to various examples.

FIG. 1B shows a plan view of a panel-level packaging system according to FIG. 1A.

FIG. 2 shows a cross-sectional view of a panel-level packaging system for integrating photonic and electronic components according to various examples.

FIG. 3A shows a cross-sectional view of an immersion cooling system to provide thermal management for a panel-level packaging system according to FIGS. 1A and 1B.

FIG. 3B shows an exploded cross-section of a panel-level packaging system according to FIG. 3A.

FIG. 4 shows a block diagram of a single-phase immersion cooling method according to FIGS. 3A and 3B.

FIG. 5 shows a block diagram of a two-phase immersion cooling method according to FIGS. 3A and 3B.

FIG. 6 shows a flowchart of a method for manufacturing a panel-level packaging system for integrating photonic and electronic components according to various examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Developments in silicon photonics have broadened the use of photonic integrated circuits (PICs) in conjunction with electrical integrated circuits (EICs) for applications in high-performance computing, telecommunications, and data center systems. These systems increasingly call for the integration of photonic and electronic components within a unified package to enhance data transfer efficiency. However, this integration introduces technical concerns, particularly regarding thermal management and the expense of existing interconnection and packaging methods.

Methods such as Embedded Multi-Die Interconnect Bridge (EMIB) and Through-Silicon Vias (TSV) have been employed to create high-speed interconnects between PICs and EICs. While these techniques provide functional solutions for smaller areas, they tend to be less economically viable for larger packages. Additionally, heat generated by photonic elements, such as lasers, can negatively affect electronic circuit performance, reducing both reliability and efficiency.

Many existing packaging designs are not enhanced to manage these combined thermal and integration challenges. In panel-level packaging, it is common practice to separate panels into individual die, which reduces the potential for package-wide thermal management solutions. Furthermore, much of the industry's focus has centered on integrating optics and electronics at the co-packaged or monolithic silicon level, with limited exploration of scalable solutions to improve thermal dissipation across full panels. Therefore, there exists a need for a packaging approach that addresses both economical high-speed interconnections and efficient heat management for panel-level systems.

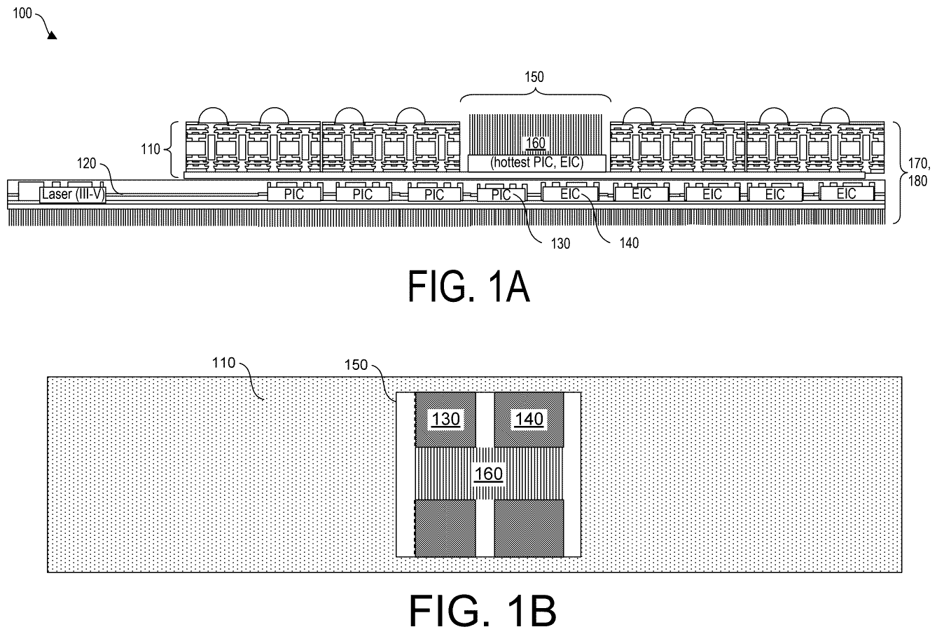

FIG. 1A shows a cross-sectional view of a panel-level packaging system 100 for integrating photonic and electronic components according to various examples. FIG. 1B shows a plan view of the panel-level packaging system 100 according to FIG. 1A.

The system 100 may include a substrate 110, which can be formed from an Ajinomoto Build-Up Film (ABF) and may provide structural support while serving as a platform for high-density interconnects between components. The ABF material may facilitate layered deposition and etching processes to form circuit paths for both photonic and electronic components. Substrate 110 can also be formed from various other materials as would be understood by a person of ordinary skill in the art. These circuit paths may enable reliable, high-speed connections between various integrated circuits.

The system 100 may include at least one photonic integrated circuit (PIC) 130 and at least one electrical integrated circuit (EIC) 140 mounted on the panel. The PIC 130 may be configured to perform optical functions such as laser transmission, photonic signal processing, and optical modulation. The EIC 140 may execute electrical processing and control functions, including driving the PIC and handling electrical input/output data. The proximity of the PIC 130 and EIC 140 to one another may improve data transfer speeds and reduce latency within the system 100.

To address the thermal challenges associated with co-packaged photonic and electronic circuits, the substrate 110 may include a window 150, which may be strategically positioned in a region where heat generation is highest. In the example of FIG. 1, the window 150 is positioned in an area corresponding to the highest thermal output, where the hottest PIC 130 and the hottest EIC 130 are located. The window 150 may be formed by etching portions of the ABF material to expose a designated area where a heat spreader 160 may be installed. The heat spreader 160 may be fabricated from highly thermally conductive materials, such as copper, aluminum, or graphite-based composites. The heat spreader 160 may be designed to draw heat away from both the PIC 130 and EIC 140, reducing thermal interference and performance degradation. Additionally, the heat spreader 160 may provide mechanical stability for the entire panel, preventing warping or damage under high operating temperatures. While FIG. 1 does not explicitly illustrate this, a thermal interface material (TIM) may be applied to facilitate thermal coupling between the PIC 130 and EIC 140 and the substrate 110. Examples of TIMs that may be used include thermal greases, phase change materials, thermal pads, metal-based TIMs such as indium or liquid metal, and thermally conductive adhesives.

The system 100 may further include embedded conductive traces 120, which serve as electrical power and signal pathways between the circuits and external interfaces. The embedded conductive traces 120 may be designed to support high-frequency signal transmission, reducing electrical losses and preserving the integrity of high-speed data communication.

The system 100 may function as a pluggable circuit board, allowing integration with modular electro-optical systems such as data center infrastructure. Electrical connectors 170 and optical connectors 180 may be positioned along the edges of the panel to establish external system connections. The optical connectors 180 may support multi-channel data transmission through fiber optic cables, while the electrical connectors 170 may provide power and control signal interfaces. Moreover, the electrical and optical connectors 170 and 180 may facilitate system 100 scalability by allowing multiple panels to be combined in a larger networked system. In various examples, the system 100 may be used with immersion cooling technologies, where a dielectric fluid may circulate around the panel to absorb heat from both the circuits and the heat spreader 160. This cooling approach may provide enhanced thermal stability for high-performance applications, such as artificial intelligence (AI) workloads and high-frequency trading systems.

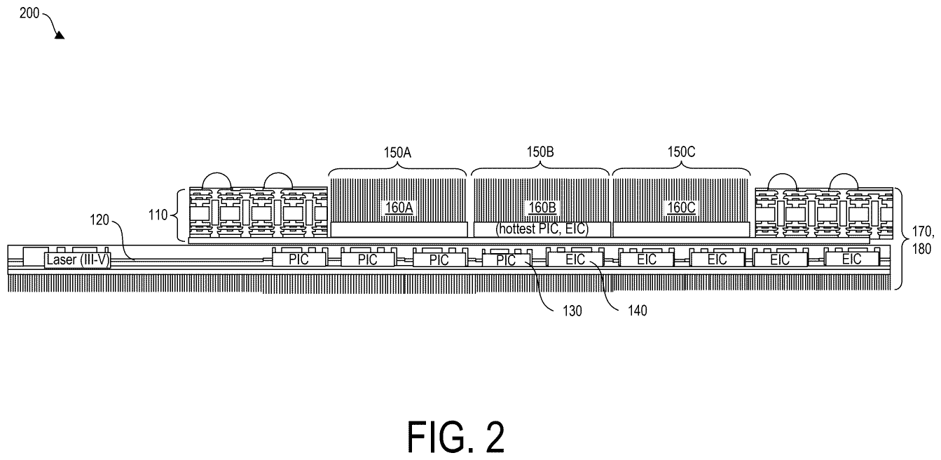

FIG. 2 shows a cross-sectional view of a panel-level packaging system 200 for integrating photonic and electronic components according to various examples. The panel-level packaging system 200 is structurally similar to the panel-level packaging system 100 in FIG. 1, except that system 200 incorporates multiple windows 150A, 150B, and 150C, each containing a respective heat spreader 160A, 160B, and 160C. In various examples, these heat spreaders may be dimensioned and shaped to enhance thermal management across different regions of the panel, allowing for more efficient dissipation of heat generated by the photonic and electronic circuits.

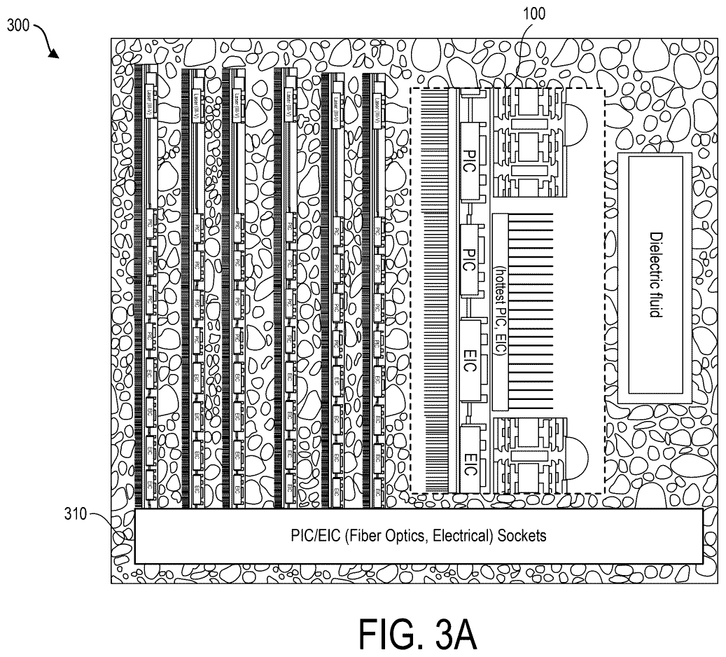

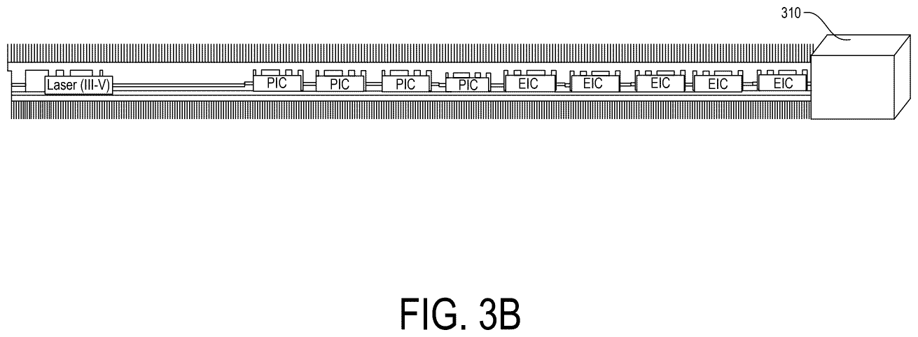

FIG. 3A shows a cross-sectional view of an immersion cooling system 300 to provide thermal management for the panel-level packaging system 100 according to FIGS. 1A and 1B. FIG. 3B shows an exploded cross-section of the panel-level packaging system 100 according to FIG. 3A.

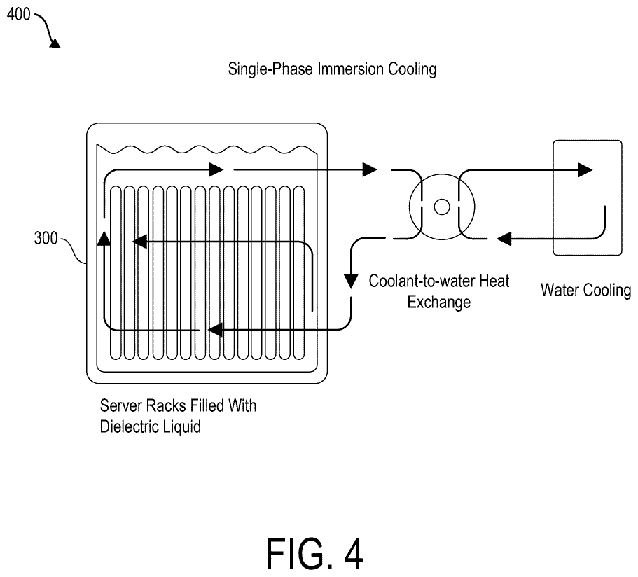

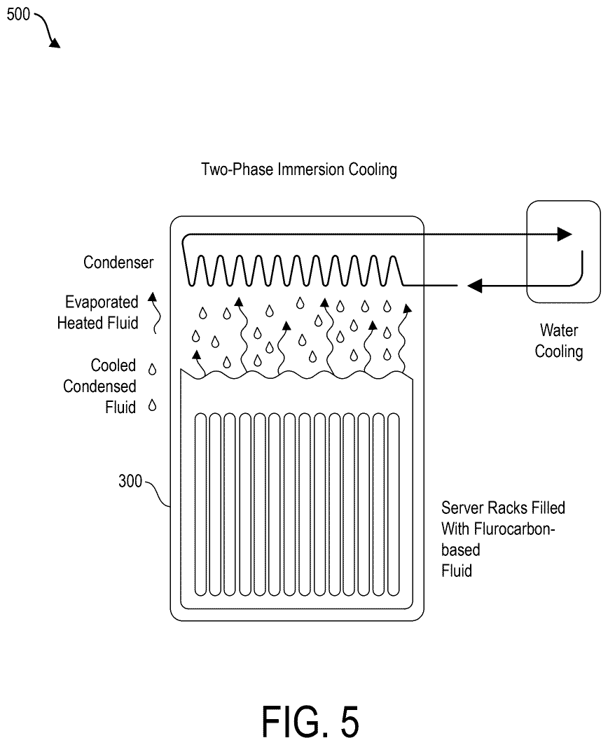

The immersion cooling system 300 may implement two types of immersion cooling methods: single-phase immersion cooling (described in FIG. 4) and two-phase immersion cooling (described in FIG. 5), both enhanced to dissipate the large amounts of heat generated by the high-performance circuits within the panel. FIG. 3A shows a panel assembly, including multiple panel-level packaging systems 100, submerged in dielectric cooling fluid, with PIC/EIC sockets 310, which provide connectivity to external systems while remaining fully submerged. The PIC/EIC sockets 310 may be configured to support stable and high-speed data transmission through fiber optics and to supply electrical power and control signals. The PIC/EIC sockets 310 for the optical connectors can be configured in different orientations to accommodate various system integration requirements. Specifically, the PIC/EIC sockets 310 may be positioned on three sides, two opposite sides, or a single side of the panel-level packaging system 100, depending on the desired connectivity layout. A three-side configuration may have the highest optical and electrical interface density, while a two-side configuration may provide balanced connections for modular integration. A one-side configuration may be used for streamlined designs where space constraints or specific cooling strategies dictate a single access point for electrical and optical connectors 170 and 180. The dielectric fluid, acting as an insulating medium, may absorb heat from components, including the PICs 130 and EICs 140, while preventing electrical short-circuits. The fluid circulation may cover thermal zones, ensuring efficient removal of heat from the panel.

FIG. 4 shows a block diagram of a single-phase immersion cooling method 400 according to FIGS. 3A and 3B. In this method 400, dielectric fluid may remain in its liquid phase throughout the process. Heat generated by the PICs 130, EICs 140, and other high-power components may be transferred to the surrounding fluid, which then rises in temperature. The heated fluid may be pumped through a coolant-to-water heat exchanger, where the heat is extracted and transferred to a secondary water cooling loop. The heat exchanger system may include thermal regulation components such as radiators, pumps, and temperature sensors for monitoring and maintaining fluid temperature. Once cooled, the dielectric fluid may recirculate back into the immersion tank, maintaining a continuous cooling cycle. This method 400 may sustain a stable operating temperature under high workloads, making it suitable for applications with moderate-to-high power density and predictable thermal output.

FIG. 5 shows a block diagram of a two-phase immersion cooling method 500 according to FIGS. 3A and 3B. In this method 500, the dielectric fluid may undergo a phase change from liquid to vapor upon absorbing sufficient heat from the panel assembly. When the fluid reaches its boiling point, it may vaporize, allowing heat dissipation through phase transition. The vapor may rise to a condenser, where it encounters a cooler surface. The condenser may transfer the heat to a water-based cooling system, causing the vapor to condense back into a liquid state. The condensed fluid may then flow back into the immersion tank, completing the cooling cycle. This latent heat of vaporization process may allow the system to handle greater thermal loads compared to single-phase cooling, as large amounts of heat can be absorbed without a corresponding increase in temperature. This method 500 may be beneficial in environments with unpredictable or high thermal peaks, where rapid heat dissipation is important to maintain system stability.

Both single-phase and two-phase immersion cooling methods 400 and 500 may provide thermal advantages for high-performance applications. Continuous and uniform heat removal may reduce thermal stress and prevent the formation of hotspots that could degrade component performance or reliability. The choice of dielectric fluid may enhance thermal conductivity, specific heat capacity, and other relevant heat transfer properties. In addition, the dielectric fluid may protect sensitive components from environmental contaminants such as dust and moisture, thereby improving system longevity. The cooling infrastructure may also support modular scalability, enabling multiple panels to be integrated within a data center and managed through centralized fluid circulation and temperature control systems. The immersion cooling system 300 may be particularly well-suited for high-performance computing, telecommunications infrastructure, and data centers, where both thermal and electrical stability are important to maintaining high performance.

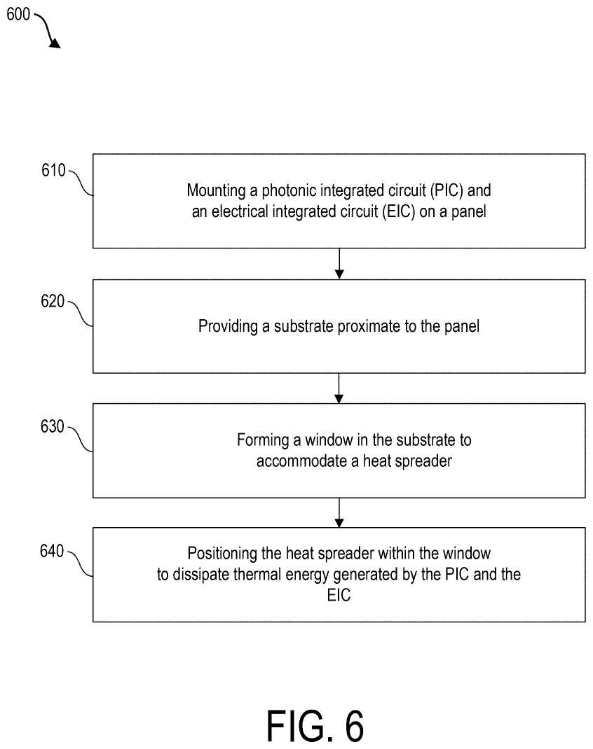

FIG. 6 shows a flowchart of a method 600 for manufacturing a panel-level packaging system for integrating photonic and electronic components according to various examples. At operation 610, the method 600 may include mounting a photonic integrated circuit (PIC) and an electrical integrated circuit (EIC) on a panel. At operation 620, the method 600 may include providing a substrate proximate to the panel. In some aspects, the substrate can be composed of an Ajinomoto Build-Up Film (ABF). At operation 630, the method 600 may include forming a window in the substrate to accommodate a heat spreader. Forming the window can include depositing and etching the substrate. At operation 640, the method 600 may include positioning the heat spreader within the window to dissipate thermal energy generated by the PIC and the EIC. The heat spreader can be positioned using a pick-and-place process.

Some aspects of method 600 can also include testing the panel for thermal performance after positioning the heat spreader. The panel can also be configured to function as a pluggable component for an electro-optical system. Further, the panel can interface with a dielectric fluid immersion cooling system.

It may be noted that the flowchart is explained to have above stated operations; however, those skilled in the art would appreciate that the flowchart may have more or less operations, which may enable all the above stated examples of the present disclosure.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A panel-level packaging system for integrating photonic and electronic components, comprising:
a substrate;
a photonic integrated circuit (PIC) and an electrical integrated circuit (EIC) mounted on a panel coupled to the substrate;
a window formed in the substrate to allow for placement of a heat spreader; and
the heat spreader positioned within the window to dissipate thermal energy generated by at least one of the PIC and the EIC.

2. The system of claim 1, wherein the panel-level packaging system is configured as a pluggable circuit board for use in an electro-optical system.

3. The system of claim 1, wherein the heat spreader is thermally coupled to at least one of the PIC and the EIC.

4. The system of claim 1, wherein the substrate includes a plurality of windows containing respective heat spreaders from a plurality of heat spreaders.

5. The system of claim 4, wherein a size and a shape of each of the plurality of heat spreaders is configured based on a thermal profile of corresponding ones of the PIC and the EIC.

6. The system of claim 1, wherein the panel-level packaging system interfaces with an immersion cooling system.

7. The system of claim 1, wherein the substrate is configured to facilitate high-density interconnects between the substrate and the panel.

8. A method for manufacturing a panel-level packaging system for integrating photonic and electronic components, comprising:
mounting a photonic integrated circuit (PIC) and an electrical integrated circuit (EIC) on a panel;
providing a substrate proximate to the panel;
forming a window in the substrate to accommodate a heat spreader; and
positioning the heat spreader within the window to dissipate thermal energy generated by the PIC and the EIC.

9. The method of claim 8, wherein forming the window comprises depositing and etching the substrate.

10. The method of claim 8, wherein the heat spreader is positioned using a pick-and-place process.

11. The method of claim 8, further comprising testing the panel for thermal performance after positioning the heat spreader.

12. The method of claim 8, further comprising configuring the panel to function as a pluggable component for an electro-optical system.

13. The method of claim 8, wherein the panel is to interface with a dielectric fluid immersion cooling system.

14. A thermal management system for a panel-level package integrating photonic and electronic circuits, comprising:
a panel, comprising a circuit of the photonic and electronic circuits;
a substrate coupled to the panel, wherein the substrate comprises a plurality of windows corresponding to thermal hotspots in the panel;
a plurality of heat spreaders positioned within the plurality of windows to dissipate the thermal hotspots; and
a dielectric cooling fluid, wherein the panel, the substrate, and the plurality of heat spreaders are submerged in the dielectric cooling fluid.

15. The system of claim 14, wherein the dielectric cooling fluid is in a liquid phase.

16. The system of claim 14, wherein the dielectric cooling fluid is in a liquid phase and undergoes a phase change to a vapor phase upon dissipating the thermal hotspots.

17. The system of claim 14, wherein the plurality of heat spreaders are comprised of a thermally conductive metal or a composite material.

18. The system of claim 14, wherein the thermal management system comprises heat spreaders proximate to both a top surface and a bottom surface of the panel.

19. The system of claim 14, wherein the panel comprises a plurality of circuits of the photonic and electronic circuits arranged in a grid pattern.

20. The system of claim 14, wherein the plurality of windows are etched to reduce disruption to conductive traces within the thermal management system.
